(19) United States
(12) Patent Application Publication
(10) Pub. No.: US 2012/0199387 A1
(43) Pub. Date: Aug. 9, 2012

(54) ELECTRONIC APPARATUS

(75) Inventor: Hiroyuki Kojo, Kawasaki-shi (JP)

(73) Assignee: CANON KABUSHIKI KAISHA, Tokyo (JP)

(21) Appl. No.: 13/360,566

(22) Filed: Jan. 27, 2012

(30) Foreign Application Priority Data
Feb. 4, 2011 (JP) 2011-022863

(51) Int. Cl. H05K 1/16

(52) U.S. Cl. 174/260

(57) ABSTRACT

An electronic apparatus includes: a circuit board on which an electronic component is mounted; a first insulation sheet arranged on the circuit board; a second insulation sheet superimposed on the first insulation sheet and bonded to the first insulation sheet; and a lead wire wired between the first insulation sheet and the second insulation sheet. The first insulation sheet and the second insulation sheet are bonded together in a region where the wiring of the lead wire is prohibited.

### BACKGROUND OF THE INVENTION

1. Field of the Invention

The present invention relates to an electronic apparatus having a circuit board and a lead wire.

2. Description of the Related Art

Conventionally, in various apparatuses containing an electronic circuit, a lead wire is fixed onto a circuit board by adhesive, double-faced tape or the like (which is discussed in Japanese Patent Application Laid-Open No. 2001-244698).

To fix a lead wire onto a circuit board, it is necessary to provide on the circuit board not only a space to which the lead wire is fixed but also a space to which adhesive is applied or a space to which double-faced tape is attached. As a result of the recent reduction in circuit board size and increase in mounting density in a portable electronic apparatus such as a digital camera, it has become rather difficult to secure such spaces on the circuit board.

### SUMMARY OF THE INVENTION

The present invention is directed to an electronic apparatus in which there is no need to secure a space to which the lead wire is to be fixed onto the circuit board and a space to which adhesive is to be applied or a space to which double-faced tape is to be attached.

According to an aspect of the present invention, an electronic apparatus includes: a circuit board on which an electronic component is mounted; a first insulation sheet arranged on the circuit board; a second insulation sheet superimposed on the first insulation sheet and bonded to the first insulation sheet; and a lead wire wired between the first insulation sheet and the second insulation sheet, wherein the second insulation sheet is bonded to the first insulation sheet in a region where the wiring of the lead wire is prohibited.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIGS. 1A and 1B are diagrams illustrating a digital camera according to an exemplary embodiment of the present invention.

FIGS. 2A, 2B, and 2C are diagrams illustrating a wiring structure for a microphone lead wire.

FIGS. 3A, 3B, 3C, and 3D are diagrams illustrating wiring procedures of microphone lead wire.

FIGS. 4A and 4B are diagrams illustrating a second exemplary embodiment of the present invention.

### DESCRIPTION OF THE EMBODIMENTS

Various exemplary embodiments, features, and aspects of the invention will be described in detail below with reference to the drawings.

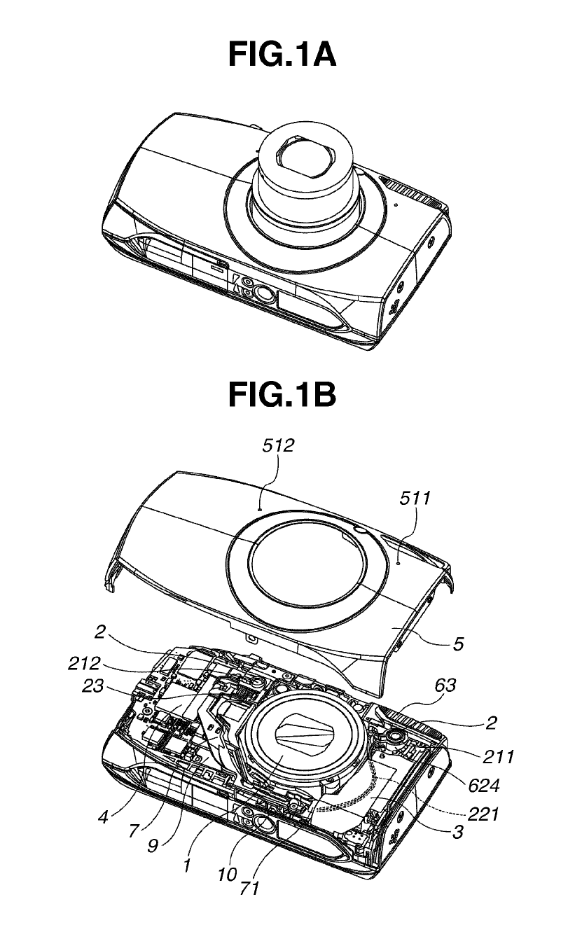

A first exemplary embodiment will be illustrated. FIG. 1A is a perspective view, as seen from the front direction (the subject direction), of a digital camera constituting an electronic apparatus according to the present invention. FIG. 1B is a perspective view, as seen from the front direction, of the digital camera of FIG. 1A with a front cover 5 removed. In FIG. 1B, a lens barrel 1 is arranged at the center of the digital camera.

A subject image having entered the camera via the lens barrel 1 is formed on an image sensor (not illustrated), and is converted to an electric signal. An insulation sheet 3 is arranged on the right-hand side of the lens barrel 1. The insulation sheet 3 serves to prevent an electronic component mounted on a flash substrate from coming into contact with the front cover 5, which is formed of metal. Here, the front cover 5 corresponds to an exterior member. The insulation sheet 3 is arranged so as to cover the flash substrate, effecting insulation between the front cover 5 and the flash substrate.

A microphone unit 2 is arranged on the right-hand side and the left-hand side of the lens barrel 1. The microphone unit 2 for stereo recording is equipped with a right-hand side microphone main body 211 and a left-hand side microphone main body 212. The right-hand side microphone main body 211 is arranged on the right-hand side of the lens barrel 1 and between a flash substrate 61 and a prism 63 constituting a flash light-emitting portion. The left-hand side microphone main body 212 is arranged on the left-hand side of the lens barrel 1 and on a main substrate 4 of the camera. The left-hand side microphone main body 212 is held by a microphone holder 7.

The right-hand side microphone main body 211 is connected to a microphone connector 23 by a microphone lead wire 221. The left-hand side microphone main body 212 is connected to the microphone connector 23 by a microphone lead wire (not illustrated). Each microphone lead wire consists of two lead wires including positive side and negative side. The microphone holder 7 is provided with a lead wire guide groove for guiding the microphone lead wire 221 leading to the right-hand side microphone main body 211 from the microphone connector 23. The microphone holder 7 is fixed to a radiator plate 9 arranged on the main substrate 4. The radiator plate 9 is formed to extend the position of a tripod portion 10, and heat-connected with the tripod portion 10. The microphone holder 7 is also formed to extend to the position of the tripod portion 10.

The microphone connector 23 is connected to a substrate connector mounted on the main substrate 4. The substrate connector to which the microphone connector 23 is connected is mounted in the vicinity of an audio integrated circuit (IC) mounted on the main substrate 4.

By unitizing the right-hand side microphone main body 211 and the left-hand side microphone main body 212, it is possible to suppress variation in characteristics depending on the microphone main body production lot. In other words, while the characteristics of the microphone main body involve a little difference depending upon the production lot, by unitizing the right and left microphones as in the present exemplary embodiment, there is no fear that microphone main bodies of different production lots in right and left are used. As a result, it is possible to omit an adjustment circuit and an adjustment process for adjusting the characteristics of the stereo microphone.

Further, since the substrate connector to which the microphone connector 23 is connected is mounted in the vicinity of the audio IC, signal lines from the microphone main bodies are little subject to the influence of noise due to other signal lines formed on the main substrate 4, enabling a reduction in noise.

When mounting the microphone unit 2, the microphone connector 23 is inserted into the substrate connector mounted on the main substrate 4. Thereafter, the microphone lead wire 221 connected to the right-hand side microphone main body 211 is dropped into a lead wire guide groove formed in the microphone holder 7. As a result, the microphone lead wire 221 is guided by the lead wire guide groove. The microphone holder 7 is formed to extend to the tripod portion 10, and the lead wire guide groove is also formed to extend to the tripod portion 10, so that the microphone lead wire 221 is wired to a right-hand end portion 71 of the microphone holder 7 along the lead wire guide groove.

After the microphone lead wire 221 has been guided to the right-hand end portion 71 of the microphone holder 7, the microphone lead wire 221 is wired within the insulation sheet 3 formed by superimposing two insulating sheet materials one upon the other. In other words, the microphone lead wire 221 is to be sandwiched between the two sheet materials constituting the insulation sheet 3.

After the microphone lead wire 221 has been sandwiched between the sheet materials of the insulation sheet, the right-hand side microphone main body 211 is fixed to a microphone holding portion 624 formed on a flash holder 62.

In the portion of the microphone lead wire 221 dropped in the lead wire guide groove, two lead wires are twisted together. As a result, the lead wire is little subject to the influence of noise due to the other signal lines formed on the main substrate 4, enabling a reduction in noise. Alternatively, in a state where the two lead wires are not twisted together, the lead wires are likely to be allowed to wriggle, and it takes time and effort to drop two lead wires simultaneously into the lead wire guide groove. However, when two lead wires are twisted together, it is easier to drop the microphone lead wire 221 into the lead wire guide groove.

On the other hand, in the portion of the microphone lead wire 221 sandwiched between the sheet materials of the insulation sheet 3, two lead wires are not twisted together. In a case where two lead wires are wired laterally side by side, the dimension in the vertical direction of the two lead wires is the outer diameter dimension of one lead wire at a maximum. In contrast, when two lead wires are twisted together, the dimension in the vertical direction of the two lead wires is the outer diameter dimension of the two lead wires at a maximum. Thus, when performing wiring in a portion where a sufficient clearance is not secured around the twisted lead wires, the lead wire may suffer damage by being pressurized.

When performing wiring in a portion where a sufficient clearance is secured around the lead wires as in the case of the lead wire guide groove of the microphone holder 7, it is desirable for the two lead wires to be twisted together from the viewpoint of ease of assembly and a reduction in noise. However, when performing wiring in a portion where a sufficient space is not secured around the lead wires, it is not desirable for the two lead wires to be twisted together from the viewpoint of reliability.

The front cover 5 is provided with a microphone hole 511 at a position corresponding to the right-hand side microphone main body 211, and a microphone hole 512 at a position corresponding to the left-hand side microphone main body 212. The right-hand side microphone main body 211 collects sound through the microphone hole 511. The left-hand side microphone main body 212 collects sound through the microphone hole 512.

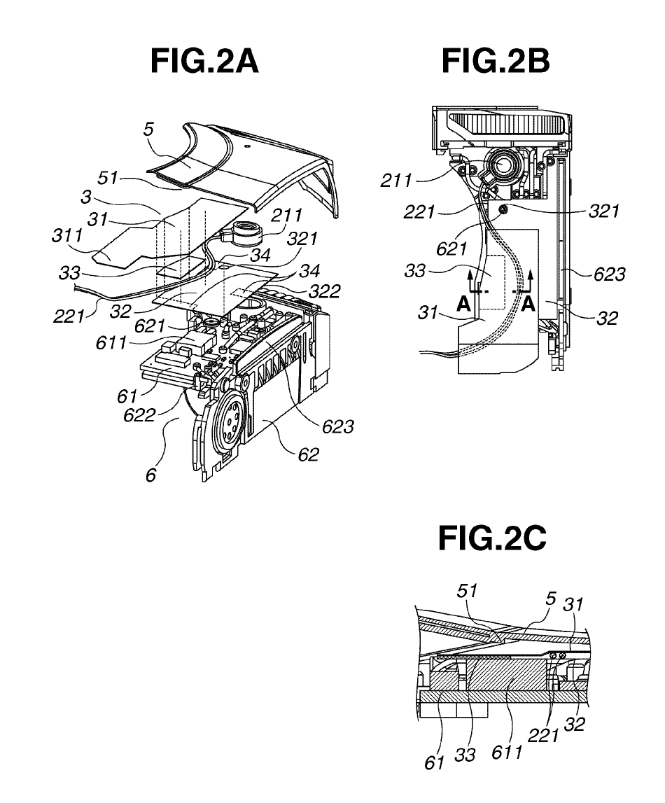

FIGS. 2A through 2C are diagrams illustrating the wiring structure for the microphone lead wire 221 on the right-hand side of the lens barrel 1. FIG. 2A is an exploded perspective view of the portion on the right-hand side of the lens barrel 1. The flash unit 6 is composed of the flash holder 62, the flash substrate 61 arranged on the flash holder 62, and the prism 63. FIG. 2B illustrates a state in which the microphone lead wire 221 is routed between an upper side insulation sheet 31 and a lower side insulation sheet 32 and in which the right-hand side microphone main body 211 is fixed to the microphone holding portion 624 formed on the flash holder 62. FIG. 2C is a sectional view taken along the line A-A of FIG. 2B.

A circuit element controlling light emission start and stop and charging is mounted on the flash substrate 61. The flash substrate 61 is set in position by bosses 621 and 622 formed on the flash holder 62, and is fastened by a screw to be thereby fixed to the flash holder 62.

The insulation sheet 3 is composed of the upper side insulation sheet 31 and the lower side insulation sheet 32, and the upper side insulation sheet 31 and the lower side insulation sheet 32 are bonded together by a first double-sided tape 33. Here, the flash substrate 61 functions as a circuit board. The lower side insulation sheet 32 corresponds to the first insulation sheet, and the upper side insulation sheet 31 corresponds to the second insulation sheet. The lower side insulation sheet 32 and the flash substrate 61 are attached together by a second double-sided tape 34, whereby the insulation sheet 3 is arranged on the flash substrate 61. The upper side insulation sheet 31, the lower side insulation sheet 32, the first double-sided tape 33, and the second double-sided tape 34 are formed of a material having an insulation property.

The lower insulation sheet 32 has a hole 321, through which the boss 621 formed on the flash holder 62 is passed; and a right-hand end portion 322 of the lower side insulation sheet 32 is caused to conform with the contour of a rib 623 provided on the flash holder 62. In this way, the lower side insulation sheet 32 is set in position with respect to the flash holder 62.

The surface of the lower side insulation sheet 32 is made milk-white through light mat finishing. If the lower side insulation sheet 32 were colorless transparent, it would become difficult to distinguish the position of the hole 321 of the lower side insulation sheet 32 and the position of the right-hand end 322 of the lower side insulation sheet 32. In the present exemplary embodiment, the lower side insulation sheet 32 is made milk-white, whereby it is easy to distinguish the position of the hole 321 of the lower side insulation sheet 32 and the position of the right-hand end 322 of the lower side insulation sheet 32. Further, the lower side insulation sheet 32 is transparent enough to allow visual recognition of the flash substrate 61 when it is set in position with respect to the flash holder 62. In this way, when the lower side insulation sheet 32 is set in position with respect to the flash holder 62, it is also possible to visually check the condition of the flash substrate 61. While in the present exemplary embodiment coloring is effected on the surface of a transparent sheet through light mat finishing, the similar effect can also be attained with a colored transparent sheet formed by adding dye to the sheet base material for light coloring.

The upper side insulation sheet 31 is formed by a colorless transparent sheet. The reason for doing so is to visually check the condition of the microphone lead wire 221 after the microphone lead wire 221 has been sandwiched between the upper side insulation sheet 31 and the lower side insulation sheet 32. Further, as stated above, the lower side insulation sheet 32 is set in position on the flash holder 62, with the upper side insulation sheet 31 and the lower side insulation sheet 32 bonded together by the first double-sided tape 33. Thus, as illustrated in FIG. 2B, when bonding the upper side insulation sheet 31 and the lower side insulation sheet 32 together, the bonding is effected such that the upper side insulation sheet 31 does not overlap the hole 321 of the lower side insulation sheet 32 and the right-hand end 322 of the lower side insulation sheet 32. When the lower side insulation sheet 32 is set in position on the flash holder 62, the upper side insulation sheet 31 and the lower side insulation sheet 32 have been attached together. In this case, if the upper side insulation sheet 31 were not a transparent sheet, it would become difficult to visually check the condition of the flash substrate 61 described above in the portion where the upper side insulation sheet 31 and the lower side insulation sheet 32 overlap each other.

As illustrated in FIG. 2B, after the upper side insulation sheet 31 and the lower side insulation sheet 32 have been bonded together by the first double-sided tape 33, the microphone lead wire 221 is wired between the upper side insulation sheet 31 and the lower side insulation sheet 32. Thus, the microphone lead wire 221 is wired in the region between the upper side insulation sheet 31 and the lower side insulation sheet 32 other than the region where the first double-sided tape is attached. In other words, the first double-sided tape 33 is to be attached to that region between the upper side insulation sheet 31 and the lower side insulation sheet 32 where the wiring of the microphone lead wire 221 is prohibited.

As illustrated in FIG. 2A, the upper side insulation sheet 31is provided with a non-overlapping region where it does not overlap the lower side insulation sheet 32. A leading end portion 311 of the non-overlapping region is formed so as to protrude from the contour of the digital camera. With this configuration, the microphone lead wire 221 can be easily wired under the upper side insulation sheet 31 solely by drawing up the microphone lead wire 221 from below the upper side insulation sheet 31 along the contour of the digital camera. In other words, it is possible to wire the microphone lead wire 221 under the upper side insulation sheet 31 without having to turn up the upper side insulation sheet 31, enabling efficiently performing the operation of putting the microphone lead wire 221 between the upper side insulation sheet 31 and the lower side insulation sheet 32.

As stated above, the microphone lead wire 221 is wired in the region between the upper side insulation sheet 31 and the lower sheet insulation sheet 32 other than the region where the first double-sided tape 33 is attached. Accordingly, when the region where the wiring of the microphone lead wire 221 is prohibited is to be changed from the viewpoint of improving the assembly workability, variation in the length of the microphone lead wire 221, etc., it is only necessary to change the configuration or attachment position of the first double-sided tape 33.

As illustrated in FIG. 2A or 2C, the front cover 5 is provided with a half-blanking-shaped portion functioning as a positioning portion when attaching covering. In the present exemplary embodiment, the half-blanking-shaped portion is formed to extend from the outer side to the inner side of the front cover 5, so that an edge portion 51 is formed on the inner side of the front cover 5. The edge portion 51 is to be one of the portions coming closest to the flash substrate 61. As illustrated in FIG. 2C, an oscillation transformer 611 of a DC-DC converter is mounted on the flash substrate 61 opposite the edge portion 51. Thus, the region opposite the edge portion 51 is a region where there is a small clearance between the upper side insulation sheet 31 and the front cover 5.

In FIG. 2C, when the microphone lead wire 221 is wired under the edge portion 51, there is a fear that the microphone lead wire 221 may get caught between the edge portion 51 and the oscillation transformer 611. Further, since the edge portion 51 is of a sharp configuration, the possibility of the edge portion 51 damaging the microphone lead wire 221 is rather high. In view of this, in the present exemplary embodiment, the first double-sided tape is attached to the region between the upper side insulation sheet 31 and the lower insulation sheet 32 which is opposite the edge portion 51. Owing to this, the region where the microphone lead wire 221 is opposite the edge portion 51 become the region where the wiring of the microphone lead wire 221 is prohibited, thus enabling preventing the microphone lead wire 221 from suffering damage.

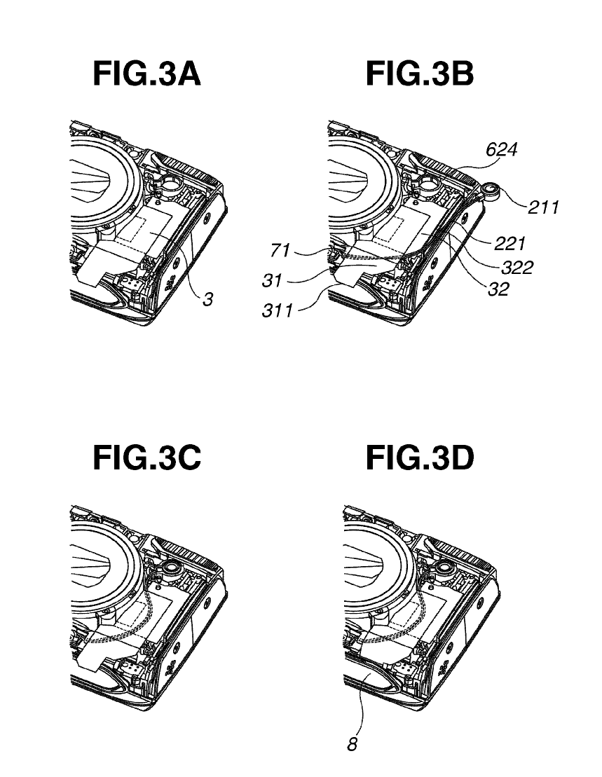

FIGS. 3A through 3D are diagrams illustrating wiring operation procedures for the microphone lead wire 221. FIG. 3A illustrates a state in which the insulation sheet 3 has been attached to the flash substrate 61. The insulation sheet 3 is set in position with respect to the flash holder 62 in the state in which the upper side insulation sheet 31 and the lower side insulation sheet 32 are attached together, and the lower side insulation sheet 32 is attached to the flash substrate 61 by the second double-sided tape 34.

FIG. 3B illustrates the state immediately before the insertion of the microphone lead wire 221 between the upper side insulation sheet 31 and the lower side insulation sheet 32.

As illustrated in FIG. 1B, the microphone lead wire 221 is wired to the right-hand end portion 71 of the microphone holder 7 along the lead wire guide groove. The operator holds the right-hand side microphone main body 211 by hand, and causes the microphone lead wire 221 to pass under the upper side insulation sheet 31 from the leading end portion 311 of the upper side insulation sheet 31. And, the microphone lead wire 221 passes over the lower side insulation sheet 32. In the present exemplary embodiment, a first non-overlapping region where the lower side insulation sheet 32 does not lie under the upper side insulation sheet 31 and a second non-overlapping region 322 where the upper side insulation sheet 31 does not overlap the lower side insulation sheet 32 are in close proximity to each other. Owing to the above configuration, the operator can put the microphone lead wire 221 between the upper side insulation sheet 31 and the lower side insulation sheet 32 without having to raise the upper side insulation sheet 31.

FIG. 3C illustrates a state in which the right-hand side microphone main body 211 has been fixed to the microphone holding portion 624 provided on the flash holder 62 after the wiring of the microphone lead wire 221 between the upper side insulation sheet 31 and the lower side insulation sheet 32. In this state, the leading end portion 311 of the upper side insulation sheet 31 is in the same condition as illustrated in FIGS. 3A and 3B.

FIG. 3D illustrates a state in which the forward end portion 311 of the upper side insulation sheet 31 has been inserted to the inner side of a bottom surface cover 11.

As illustrated in FIGS. 3A through 3C, the forward end portion 311 of the upper side insulation sheet 31 is formed so as to protrude from the contour of the digital camera. By inserting the forward end portion 311 protruding from the contour of the digital camera to the inner side of the bottom surface cover 11, there is no fear that the upper side insulation sheet 31 will be turned up during the operation of mounting the front cover 5. Further, the microphone lead wire 221 is covered with the upper side insulation sheet 31 starting from the right-hand end portion 71 of the microphone holder 7, so that there is no fear of the microphone lead wire 221 being drawn out during the operation of mounting the front cover 5.

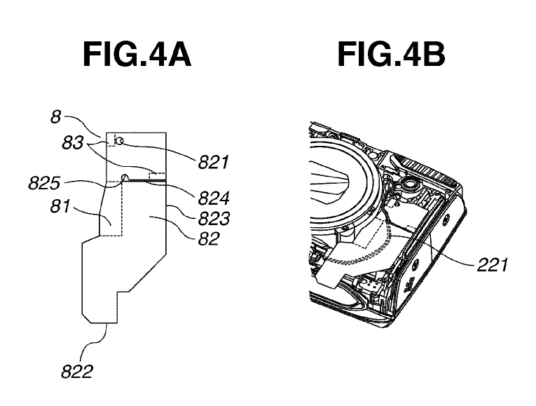

A second exemplary embodiment of the present invention will be illustrated with reference to FIGS. 4A and 4B. An illustration of the portions that are similar to those of the first exemplary embodiment will be left out. FIG. 4A is a diagram illustrating the configuration of an insulation sheet 8, and FIG. 4B is a perspective view illustrating how the microphone lead wire 221 is wired. In FIG. 4A, the insulation sheet 8 is configured with an insulation sheet main body 82, a double-sided tape 81 and two double-sided tape 83. The double-sided tape 81 and 83 are attached to the insulation sheet main body 82. The insulation sheet main body 82 and the double-sided tape 81 and 83 are formed of a material having an insulation property.

A hole 821 is formed in the insulation sheet main body 82, and a boss 621 formed on the flash holder 62 is passed through the hole 82, with a right-hand end portion 823 of the insulation sheet main body 82 conforming with the contour of a rib 623 provided on the flash holder 62. In this way, the insulation sheet main body 82 is set in position with respect to the flash holder 62.

One surface of each of the double-sided tapes 81 and 83 is attached to the insulation sheet main body 82, and the other surface thereof is attached to the flash substrate 61. By this configuration, the insulation sheet main body 82 is attached to the flash substrate 61. As in the case of the first double-sided tape 33 of the first exemplary embodiment, the double-sided tape 81 is attached to a region opposite the edge portion 51.

A slit 824 is formed in the insulation sheet main body 82. The slit 824 is formed in a width smaller than the outer diameter dimension of the microphone lead wire 221. A lead wire fixing portion 825 is formed at an end of the first slit 824. The lead wire fixing portion 825 has a diameter larger than double the outer diameter dimension of the microphone lead wire 221 so that the microphone lead wire 221, which is composed of two lead wires, can enter it in a sufficiently stable manner. In other words, there is a difference between the width of the slit 824 and the diameter of the lead wire fixing portion 825. Thus, when the microphone lead wire 221 has been put in the lead wire fixing portion 825, there is no fear of the microphone lead wire 221 being detached from the lead wire fixing portion 825. Further, by forming the lead wire fixing portion 825 in a curved-line contour, it is possible to prevent rupture occurring from the end portion of the slit 824.

The double-sided tape 83 is attached to the portion in the vicinity of the hole 821 and to the upper end portion of the slit 824. By attaching the insulation sheet main body 82 to the flash substrate 61 in the vicinity of the hole 821, it is possible to prevent the insulation sheet main body 82 being detached from the boss 621. Further, by attaching the insulation sheet main body 82 to the flash substrate 61 at the upper end portion of the slit 824, the microphone lead wire 221 can be easily put in the slit 824. When performing the operation of putting the microphone lead wire 221 in the slit 824, the operator holds the right-hand side microphone main body 211, and causes the microphone lead wire 221 to pass under the insulation sheet main body 82 from the leading end portion 822 of the insulation sheet main body 82, putting the microphone lead wire 221 in the slit 824. In this case, the upper end portion of the slit 824 is attached to the flash substrate 61 by the double-sided tape 83, and the lower end portion of the slit 824 is not attached to, so that solely the lower end portion of the slit 824 is turned up. In this way, the operator can put the microphone lead wire 221 in the slit 824 without having to raise the insulation sheet main body 82.

As illustrated in FIG. 4B, the microphone lead wire 221 is caused to pass under the leading end portion 822 of the insulation sheet main body 82, and is put in the lead wire fixing portion 825 from the slit 824. In this way, the microphone lead wire 221 is guided to a position above the insulation sheet main body 82. In the present exemplary embodiment, the microphone lead wire 221 is thus wired over and under the insulation sheet main body 82.

In the region opposite the edge portion 51, the double-sided tape 81 bonds the insulation sheet main body 82 and the flash substrate 61 together. Thus, in the case where the microphone lead wire 221 is wired between the insulation sheet main body 82 and the flash substrate 61, the portion to which the double-sided tape 81 is attached is the region where the wiring of the microphone lead wire 221 is to be prohibited.

In the region opposite the edge portion 51 of the front cover 5, the microphone lead wire 221 is wired under the insulation sheet main body 82, and, in the region opposite the edge portion 51, the insulation sheet main body 82 is attached to the flash substrate 61. Thus, there is no fear that the microphone lead wire 221 is wired in the region opposite the edge portion 51, thus providing similar effect to that of the first exemplary embodiment described above.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2011-022863 filed Feb. 4, 2011, which is hereby incorporated by reference herein in its entirety.

What is claimed is:

1. An electronic apparatus comprising:
a circuit board mounted with an electronic component;
a first insulation sheet arranged on the circuit board;
a second insulation sheet superimposed on the first insulation sheet and bonded to the first insulation sheet; and
a lead wire to be wired between the first insulation sheet and the second insulation sheet,
wherein the second insulation sheet is bonded to the first insulation sheet in a region where the wiring of the lead wire is prohibited.

2. The electronic apparatus according to claim 1, wherein the first insulation sheet is formed with a positioning portion to effect positioning when arrangement is effected on the circuit board, and
wherein the second insulation sheet is superimposed on the first insulation sheet so the second insulation sheet does not overlap the positioning portion.

3. The electronic apparatus according to claim 1, wherein the first insulation sheet is formed of a colored transparent material, and
wherein the second insulation sheet is formed of a colorless transparent material.

4. The electronic apparatus according to claim 1, wherein the second insulation sheet is formed with a non-overlapping region not overlapping the first insulation sheet, and
wherein a leading end portion of the non-overlapping region protrudes from the contour of the electronic apparatus.

5. The electronic apparatus according to claim 1, wherein the first insulation sheet and the second insulation sheet are bonded together by a double-sided tape having an insulation property.

6. The electronic apparatus according to claim 1, further comprising:
an exterior member arranged to cover the second insulation sheet,
wherein a region where the clearance between the second insulation sheet and the exterior member is small is the region where the wiring of the lead wire is prohibited.

7. An electronic apparatus comprising:
a circuit board mounted with an electronic component;
an insulation sheet arranged on the circuit board; and
a lead wire to be wired between the circuit board and the insulation sheet,
wherein the circuit board and the insulation sheet are bonded together in a region where the wiring of the lead wire is prohibited.

8. The electronic apparatus according to claim 7, wherein a leading end portion of the insulation sheet protrudes from the contour of the electronic apparatus.

9. The electronic apparatus according to claim 7, wherein the circuit board and the insulation sheet are together by a double-sided tape having an insulation property.

10. The electronic apparatus according to claim 7, further comprising: an exterior member arranged so as to cover the insulation sheet,
wherein a region where the clearance between the insulation sheet and the exterior member is small is the region where the wiring of the lead wire is prohibited.
